(19) United States
(12) Patent Application Publication
(10) Pub. No.: US 2012/0169360 A1
(43) Pub. Date: Jul. 5, 2012

(54) SYSTEM AND METHODS FOR TESTING ELECTRICAL POWER SYSTEM COMPONENTS

(75) Inventors: Eric M. Andris, Chillicothe, IL (US); Robert W. Lindsey, Washington, IL (US)

(73) Assignee: Caterpillar Inc.

(21) Appl. No.: 12/981,384

(22) Filed: Dec. 29, 2010

(51) Int. Cl. G01R 31/00

(52) U.S. Cl. 324/750.01

(57) ABSTRACT

A power system includes a prime mover drivingly connected to an electric generator. The power system may also include an electric power load, an electrical energy storage device, and power-system controls. The power-system controls may be configured to selectively operate the prime mover and the electric generator to power the electric power load by supplying electricity at a first voltage. The power-system controls may also be configured to selectively supply electricity from the electrical energy storage device at a second voltage during testing of one or more electrical components of the power system with the electricity supplied at the second voltage. The second voltage may be lower than the first voltage.

### TECHNICAL FIELD

The present disclosure relates to power systems having electrical components and, more particularly, to testing of the electrical components of such power systems.

### BACKGROUND

Many machines include a power system with electrical components. For example, many machines include one or more electric power loads and one or more electrical power sources, such as an electric generator driven by a prime mover (e.g., an engine), for powering those electrical power loads. To ensure that such a power system can operate properly, it may be helpful to test the operation of one or more of the electrical components of the power system. Some such testing may involve supplying electricity to one or more electrical components of the power system and measuring one or more parameters to determine the condition of one or more electrical components.

Published U.S. Patent Application No. 2009/0251154 A1 to Lindsey (“the '154 application”) discloses methods for testing one or more electrical components of a power system. The '154 application discloses using an engine and electric generator to supply electricity for testing. With the electricity supplied by the engine and electric generator, the '154 patent discloses testing the integrity of electrical insulation in the power system.

Although an engine and electric generator may provide a useful source of electricity for testing one or more electrical components of a power system, using electricity from an engine and electric generator to supply electricity for testing operations may have certain drawbacks. For example, if an electrical short or similar problem should occur during testing, the large power capacity of an engine and electric generator may result in excessive current flowing in one or more portions of the electrical system, which could damage one or more electrical components. Additionally, operating an engine and electric generator may create significant electrical and electromagnetic noise, which may interfere with electrical testing.

The power system and methods of the present disclosure solve one or more of the problems set forth above.

### SUMMARY

One disclosed embodiment relates to a power system. The power system may include a prime mover drivingly connected to an electric generator. The power system may also include an electric power load, an electrical energy storage device, and power-system controls. The power-system controls may be configured to selectively operate the prime mover and the electric generator to power the electric power load by supplying electricity at a first voltage. The power-system controls may also be configured to selectively supply electricity from the electrical energy storage device at a second voltage during testing of one or more electrical components of the power system with the electricity supplied at the second voltage. The second voltage may be lower than the first voltage.

Another embodiment relates to a method of operating a power system. The power system may include a prime mover, an electric generator drivingly connected to the prime mover, an electric power load, and an electric energy storage device. The method may include selectively operating the prime mover and the electric generator to supply electricity at a first voltage to power the electric power load. The method may also include selectively supplying electricity at a second voltage with the electrical energy storage device while testing one or more electrical components of the power system with the electricity supplied from the electrical energy storage device at the second voltage, wherein the second voltage is lower than the first voltage.

A further disclosed embodiment relates to a machine. The machine may include a power system. The power system may include an electric motor, an engine drivingly connected to an electric generator, and a power line connected between the electric generator and the electric motor, the power line being operable to transmit electricity between the electric generator and the electric motor. The power system may also include a first electrical energy storage device, a second electrical energy storage device, and power-system controls. The power-system controls may be configured to selectively operate the engine and the electric generator to supply electricity to the power line while exchanging electricity between the first electrical energy storage device and the power line. The power-system controls may also be configured to selectively operate the power system in a testing mode with the engine shut down and the second electrical energy storage device supplying electricity to the power line while tests are performed on one or more electrical components of the power system with the electricity supplied to the power line by the second electrical energy storage device.

### BRIEF DESCRIPTION OF THE DRAWINGS

FIG. 1 shows one embodiment of a machine having a power system according to the present disclosure; and

FIG. 2 shows one embodiment of a power system according to the present disclosure in more detail.

### DETAILED DESCRIPTION

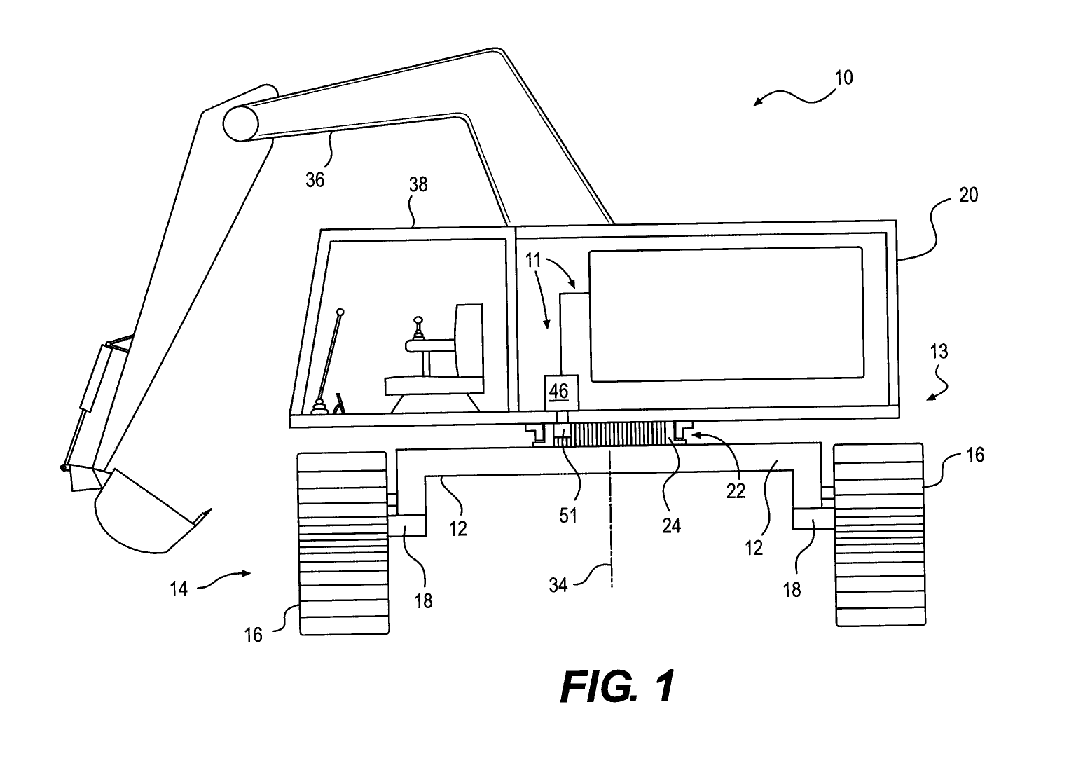

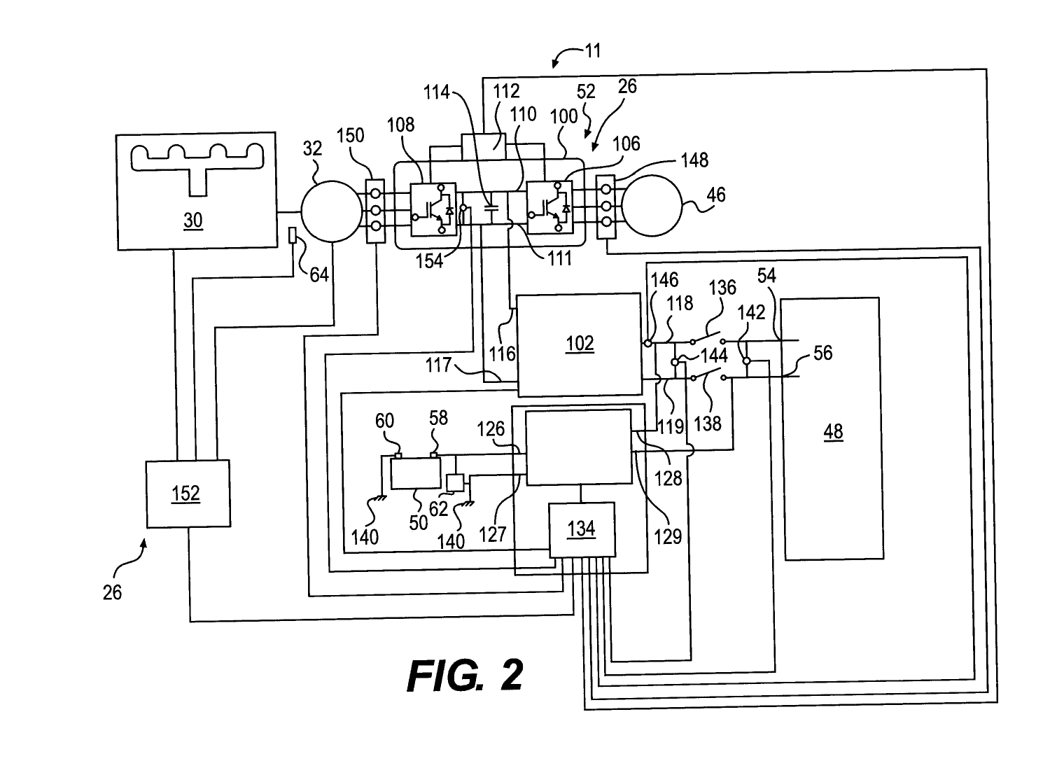

FIGS. 1 and 2 show a machine 10, a power system 11, and various components thereof according to the present disclosure. Machine 10 may be any type of machine that employs power to perform one or more tasks. For example, machine 10 may be a mobile machine configured to transport or move people, goods, or other matter or objects. Additionally, or alternatively, machine 10 may be configured to perform a variety of other operations associated with a commercial or industrial pursuit, such as mining, construction, energy exploration and/or generation, manufacturing, transportation, and agriculture.

As shown in FIG. 1, in some embodiments, machine 10 may be an excavator configured for digging. Machine 10 may include a chassis 13 to which other components of machine 10 are attached. In some embodiments, chassis 13 may be constructed in part or in whole from electrically conductive materials, such as steel, cast iron, aluminum, and/or other electrically conductive metals. In the example shown in FIG. 1, chassis 13 may include an undercarriage 14 and a superstructure 20. Undercarriage 14 may include a frame 12. In some embodiments, machine 10 may be a mobile machine, and undercarriage 14 may include one or more propulsion devices 16 for propelling machine 10. Propulsion devices 16 may be any type of device configured to propel machine 10. For example, as FIG. 1 shows, propulsion devices 16 may be track units. Alternatively, propulsion devices 16 may be wheels or other types of devices operable to propel machine 10. Undercarriage 14 may also include one or more components for driving propulsion devices 16. For example, undercarriage 14 may include drive motors 18 for driving propulsion devices 16. Drive motors 18 may be electric motors or hydraulic motors.

Superstructure 20 may be suspended from frame 12. In some embodiments superstructure 20 may be suspended from frame 12 by a pivot system 22. Pivot system 22 may include a swing bearing 24 and an electric motor 46. Swing bearing 24 may include an inner race mounted to frame 12 and an outer race to which superstructure 20 mounts. Both the inner and outer race of swing bearing 24 may extend concentric to a vertical axis 34. The inner and outer race may be engaged to one another via rolling elements (not shown), such as ball bearings, in such a manner that the outer race and superstructure 20 may pivot around axis 34 relative to frame 12.

Electric motor 46 may be operable to rotate superstructure 20 and the outer race of swing bearing 24 around axis 34. Electric motor 46 may have a gear 51 mounted to its output shaft, and electric motor 46 may mount to superstructure 20 in a position such that gear 51 meshes with gear teeth on frame 12. Electric motor 46 may receive power to rotate superstructure 20 around axis 34 from various components of power system 11. Electric motor 46 may constitute one of many electrical power loads of power system 11.

Machine 10 may include various other components. For example, as FIG. 1 shows, machine 10 may include an implement 36. Implement 36 may be mounted to various parts of machine 10 and configured to perform various tasks. In some embodiments, implement 36 may be mounted to superstructure 20 and configured to perform digging. Machine 10 may also include an operator station 38 from which an individual can control one or more aspects of the operation of machine 10. Operator station 38 may also be mounted to superstructure 20.

FIG. 2 shows power system 11 in greater detail. Power system 11 may include power-system controls 26 and various components operable to provide power to perform various tasks. In some embodiments, power system 11 may be a hybrid-electric power system. In addition to power-system controls 26, power system 11 may include electric motor 46, a prime mover 30, an electric motor/generator 32, a first electrical energy storage device 48, a second electrical energy storage device 50, and a power-transmission system 52. As used herein, the term “electric motor/generator” refers to any electrical device operable to operate as an electric motor when receiving electrical power and/or to operate as an electric generator when being mechanically driven.

Prime mover 30 may be any type of device configured to produce mechanical power to drive electric motor/generator 32. For example, prime mover 30 may be a diesel engine, a gasoline engine, a gaseous fuel-powered engine, or any other type of component operable to produce mechanical power.

Electric motor/generator 32 may be any type of component operable to generate electricity with mechanical power received from prime mover 30. Electric motor/generator 32 may also be operable to receive electricity and operate as an electric motor to drive prime mover 30 for a number of purposes. Electric motor 46 may be any type of component operable to receive electricity from power-transmission system 52 and operate as an electric motor. Each of electric motor/generator 32 and electric motor 46 may be, for example, any of a permanent-magnet electric machine, a switched reluctance electric machine, a DC electric machine, an induction-type machine or any other type of electric machine known in the art.

Electrical energy storage device 48 may be any type of device operable to store electrical energy and exchange electricity with (i.e., receive electricity from and transmit electricity to) power-transmission system 52. For example, electrical energy storage device 48 may include one or more batteries and/or one or more capacitors. Electrical energy storage device 48 may include a positive terminal 54 and a negative terminal 56. Electrical energy storage device 48 may be electrically isolated from the chassis 13 of machine 13. Electrical energy storage device 48 may include one or more storage cells (not shown) electrically connected to positive and negative terminals 54, 56. In some embodiments, electrical energy storage device 48 may include multiple storage cells electrically connected in series and/or parallel to positive and negative terminals 54, 56.

Electrical energy storage device 48 may also include various other electrical components connected to terminals 54, 56 and/or the storage cells. For example, in some embodiments where electrical energy storage device 48 includes multiple energy storage cells connected to one another, electrical energy storage device 48 may include one or more circuits for allowing the flow of electricity around one or more cells during charging and/or discharging of electrical energy storage device 48. These and other components of electrical energy storage device 48 may be able to carry only limited current in certain circumstances, such as during charging of electrical energy storage device 48 in order to balance the charge of the cells in circumstances where the relative charge levels of its storage cells has become imbalanced.

Electrical energy storage device 48 may serve as the primary electrical energy storage for power system 11. Accordingly, electrical energy storage device 48 may have a large energy storage capacity. Additionally, electrical energy storage device 48 may have a relatively high nominal voltage rating, such as approximately 350 volts.

Electrical energy storage device 50 may also be any type of device operable to store electrical energy and exchange electricity with (i.e., receive electricity from and transmit electricity to) power-transmission system 52. Like electrical energy storage device 48, electrical energy storage device 50 may include one or more batteries and/or one or more capacitors. Electrical energy storage device 50 may include a positive terminal 58 and a negative terminal 60. In some embodiments, one of terminals 58, 60 may be electrically connected to chassis 13, so that the voltage of the terminal 58, 60 is chassis referenced. For example, negative terminal 60 may be electrically connected to chassis 13 via an electrical ground 140. Electrical energy storage device 50 may serve as a secondary electrical energy store of power system 11. Additionally, electrical energy storage device 50 may have a significantly lower nominal voltage rating than energy storage device 48. For example, electrical energy storage device 50 may have a nominal voltage rating of approximately 12 volts or approximately 24 volts.

Power-transmission system 52 may include an inverter 100, a power regulator 102, a power regulator 104, and various electrical connectors, such as electric lines and/or electric switches connecting these devices. Inverter may 100 include a power electronics unit 106, a power electronics unit 108, power lines 110, 111, a bulk capacitor 114, and a controller 112. Power electronics unit 106 may be operable to regulate a flow of power between electric motor 46 and power lines 110, 111. Power electronics module 106 may also be operable to convert the form of electricity flowing between electric motor 46 and power lines 110, 111. For example, power electronics unit 106 may be operable to convert between alternating electric current at electric motor 46 and direct current at power lines 110, 111. Power electronics module 108 may similarly be operable to regulate a flow of power between electric motor/generator 32 and power lines 110, 111. Power electronics module 108 may also be able to convert the form of electricity flowing between electric motor/generator 32 and power lines 110, 111, such as converting between alternating current electricity at electric motor/generator 32 and direct current electricity at power lines 110, 111. Power electronics modules 106-108 may include various types of controllable electric components for regulating and/or converting electrical power, including, but not limited to SCRs (silicon controller rectifiers), GTOs (gate turn-offs), IGBTs (insulated gate bipolar transistors), and FETs (field-effect transistors). Bulk capacitor 114 may be connected between power lines 110, 111 and serve to smooth out any fluctuations in voltage across power lines 110, 111. This configuration of inverter 100 may allow exchange of electricity between electric motor/generator 32 and electric motor 46 via power electronics modules 106, 108 and power lines 110, 111.

Controller 112 may be operatively connected to power electronics modules 106, 108, and controller 112 may be configured (e.g., programmed) to control one or more aspects of the operation of power electronics modules 106, 108. In some embodiments, controller 112 may include, for example, one or more microprocessors and/or one or more memory devices. By controlling power electronics modules 106, 108, controller 112 may be operable to control the voltage on power lines 110, 111, as well as the magnitude of current flowing between power lines 110, 111, electric motor 46, and electric motor/generator 32. In some embodiments, controller 112 may control power electronics modules to maintain voltage on power lines 110, 111 higher than the nominal voltage rating of electrical energy storage device 48. For example, where the nominal voltage rating of electrical energy storage device 48 is about 350 volts, controller 112 may operate power electronics modules 106, 108 to maintain the voltage on power lines at about 650 volts.

Power regulator 102 may include input/output terminals 116, 117, 118, 119. Power regulator 102 may have any configuration that allows it to regulate one or more aspects of electricity exchanged between terminals 116, 117 and terminals 118, 119. Power regulator 102 may, for example, be operable to control whether electricity is exchanged between terminals 116, 117 and terminals 118, 119. Power regulator 102 may also be configured to control which direction electricity flows between terminals 116, 117 and terminals 118, 119, i.e., whether electricity flows from terminals 116, 117 to terminals 118, 119, or vice-a-versa. Power regulator 102 may exchange electricity in various forms. In some embodiments, power regulator 102 may be configured to receive and/or supply direct current electricity at terminals 116, 117, 118, 119. Power regulator 102 may also be operable to control the voltage at each of terminals 116, 117, 118, 119 as well as the magnitude of electric current flowing at each of terminals 116, 117, 118, 119. For example, power regulator 102 may be operable to change the electricity transmitted between terminals 116, 117 and terminals 118, 119 from one voltage (such as approximately 650 volts) of direct current electricity at terminals 116, 117 to another voltage (such as approximately 350 volts) of direct current electricity at terminals 118, 119. As discussed further below, power regulator 102 may be controllable by one or more other component(s) of power system 11, so that those other components may control how power regulator 102 controls the exchange of electricity between terminals 116, 117 and terminals 118, 119. Power regulator 102 may include any suitable configuration of components that allows it to provide the above-discussed functionality.

Power regulator 104 may include input/output terminals 126, 127, 128, 129. Power regulator 104 may have any configuration that allows it to regulate one or more aspects of electricity exchanged between terminals 126, 127 and terminals 128, 129. Power regulator 104 may, for example, be operable to control whether electricity is exchanged between terminals 126, 127 and terminals 128, 129. Power regulator 104 may exchange electricity in various forms. In some embodiments, power regulator 104 may be configured to receive and/or supply direct current electricity at terminals 126, 127, 128, 129. Power regulator 104 may also be operable to control the voltage at each of terminals 126, 127, 128, 129 as well as the magnitude of electric current flowing at each of terminals 126, 127, 128, 129. For example, power regulator 104 may be operable to change the electricity transmitted between terminals 126, 127 and terminals 128, 129 from one voltage (such as approximately 12 or 24 volts) of direct current electricity at terminals 126, 127 to another voltage (such as approximately 350 volts) of direct current electricity at terminals 128, 129.

Power regulator 104 may be a unidirectional or bidirectional power regulator. In embodiments where power regulator 104 is a unidirectional power regulator, power regulator 104 may be operable to transmit electricity in only one direction between terminals 126, 127 and terminals 128, 129. For example, in some embodiments, power regulator 104 may be operable to transmit electricity from terminals 126, 127 to terminals 128, 129 but not in the opposite direction. Conversely, in embodiments where power regulator 104 is a bidirectional power regulator, power regulator 104 may be configured to control which direction electricity flows between terminals 126, 127 and terminals 128, 129, i.e., whether electricity flows from terminals 116, 117 to terminals 118, 119, or vice-a-versa.

Power regulator 104 may include a controller 134 configured (e.g., programmed) to control the foregoing aspects of how power regulator 104 controls the exchange of electricity between its terminals 126, 127, 128, 129. Controller 134 may have any configuration allowing it to perform such control of power regulator 104. In some embodiments, controller 134 may include one or more microprocessors and/or one or more memory devices. Controller 134 may also be operatively connected to power regulator 102 and controller 112 of inverter 100, so that controller 134 may monitor and/or control one or more aspects of the operation of power regulator 102 and inverter 100. As discussed further below, controller 134 and power regulator 104 may be operatively connected to other components of power-system controls 26, so that those other components may provide information to and/or control one or more aspects of how controller 134 controls power regulator 104, power regulator 102, and inverter 100. Power regulator 104 may include any suitable configuration of components that allows it to provide the above-discussed functionality.

In some embodiments, power regulator 104 may be operable to control small quantities of electric current more precisely than power regulator 102. For example, power regulator 104 may be operable to provide stable, effective control of the current magnitude and voltage of electric currents measured in milliamps, whereas power regulator 102 may be configured to control much larger power levels, such as electric current magnitudes in the tens or hundreds of amps. Concomitantly, power regulator 102 may, in some embodiments, have a higher power capacity than power regulator 104. For example, power regulator 102 may have a power capacity of tens, hundreds, or thousands of times that of power regulator 104.

Inverter 100, power regulators 102, 104, electrical energy storage devices 48, 50, electric motor 46, and electric motor/generator 32 may be electrically connected to one another in various ways. As FIG. 2 shows, in some embodiments, terminals 116, 117 of power regulator 102 may be electrically connected to power lines 110, 111 of inverter 100. This may allow exchange of electricity between power regulator 102, electric motor 46, and electric motor/generator 32 via power lines 110, 111 of inverter 100.

Additionally, power-transmission system 52 may have provisions for connecting terminals 118, 119 of power regulator 102 directly or indirectly to each of power regulator 104, electrical energy storage device 48, and electrical energy storage device 50. Terminal 118 of power regulator 102 may, for example, be continuously electrically connected to terminal 128 of power regulator 104. Additionally, power-transmission system 52 may include a switching device 138 that is operable when closed to electrically connect terminal 119 of power regulator 102 to terminal 129 of power regulator 104. Thus, when switching device 138 is in the closed operating state such that terminals 118, 119 of power regulator 102 are electrically connected to terminals 128, 129 of power regulator 104, power regulators 102, 104 may exchange electricity between one another, and power regulator 102 may be indirectly connected to electrical energy storage device 50 through power regulator 104. Conversely, when switching device 138 is in its open operating state, power regulator 102 and power regulator 104 may be effectively electrically isolated from one another.

Switching device 138 may also be operable to electrically connect terminal 119 of power regulator 102 to negative terminal 56 of electrical energy storage device 48. Additionally, power-transmission system 52 may include a switching device 136 operable when in its closed operating state to electrically connect terminal 118 of power regulator 102 to positive terminal 54 of electrical energy storage device 48. Thus, when switching devices 136, 138 are in their closed operating states, power regulator 102 and electrical energy storage device 48 may exchange electricity between one another. Conversely, when either of switching devices 136, 138 is in an open operating state, electrical energy storage device 48 may be effectively electrically isolated from power regulator 102. Switching devices 136, 138 may be controlled by various other components of power-system controls 26. In some embodiments, switching devices 136, 138 may be controlled, for example, by controller 134.

Power-transmission system 52 may also be configured to allow exchange of electricity between power regulator 104 and electrical energy storage device 48. Terminal 129 of power regulator 104 may, for example, be continuously electrically connected to negative terminal 56 of electrical energy storage device 48. Additionally, as noted above, terminal 128 of power regulator 104 may be continuously electrically connected to terminal 118 of power regulator 102, and switching device 136 may be operable when in a closed operating state to electrically connect terminal 118 of power regulator 102 to positive terminal 54 of electrical energy storage device 48. Thus, when switching device 136 is in a closed operating state, power regulator 104 and electrical energy storage device 48 may exchange electricity between one another. Conversely, when switching device 136 is in an open operating state, power regulator 104 and electrical energy storage device 48 may be effectively electrically isolated from one another.

Power-transmission system 52 may also have provisions for transmitting electricity between electrical energy storage device 50 and power regulator 104. For example, terminal 126 of power regulator 104 may be continuously connected to positive terminal 58 of electrical energy storage device 50. Additionally, negative terminal 60 of electrical energy storage device 50 and terminal 127 of power regulator 104 may be electrically connected to a common electrical ground, 140, such as an electrically conductive portion of chassis 13 of machine 10.

The exemplary configuration of power-transmission system 52 shown in FIG. 2 may allow it to transmit electricity between electric motor/generator 32, electric motor 46, electrical energy storage device 48, and electrical energy storage device 50 in various ways through power regulators 102, 104. For example, when switching device 136 is in a closed operating state and switching device 138 is in an open operating state, power-transmission system 52 may transmit electricity between electrical energy storage device 50 and electrical energy storage device 48 via power regulator 104. When switching device 136 is in an open operating state and switching device 138 is in a closed operating state, power-transmission system 52 may transmit electricity between electrical energy storage device 50, electric motor/generator 32, and electric motor 46 via power regulators 102, 104. When both switching devices 136, 138 are closed, power-transmission system 52 may freely exchange electricity between electrical energy storage device 48, electrical energy storage device 50, electric motor/generator 32, and electric motor 46 through one or both of power regulators 102, 104.

In addition to those shown in FIG. 2, power system 11 may also include a number of other electrical loads and/or sources. For example, in addition to electric motor 46, power system 11 may include various other large, high-voltage electrical loads, such as drive motors 18, connected to power lines 110, 111 of inverter 100. Additionally, power system 11 may have various electrical loads 62 connected to electrical energy storage device 50, which may be smaller, low-voltage loads, such as lights, gauges, sensors, fan motors, and the like. Such loads 62 may be connected to electrical energy storage device 50 through a low-voltage power-transmission system, separate from power-transmission system 52. Additionally, power system 11 may include one or more electricity sources for charging electrical energy storage device 50 and/or powering any smaller, low-voltage loads connected thereto. For example, power system 11 may include a conventional alternator (not shown) driven by prime mover 30. Electrical power loads 62, the low-voltage power-transmission system connecting them to electrical energy storage device 50, and any other electrical energy sources connected to electrical energy storage device 50 and electrical power loads 62 may be electrically referenced to chassis 13, such as by connection to ground 140.

Power-system controls 26 may be configured to control charging and discharging of electrical storage devices 48, 50, operation of prime mover 30, operation of electric motor/generator 32, operation of electric motor 46, and transmission of electricity through power-transfer system 52 in connection with all of these tasks. Power-system controls 26 may include a number of the components already discussed, such as inverter 100, power regulator 102, power regulator 104, and switching devices 136, 138. To control the operation of these components, some embodiments of power-system controls 26 may include one or more other components. For example, as FIG. 2 shows, power-system controls 26 may include a controller 152 operably connected to controller 134 of power regulator 104. Controller 152 may also be operatively connected to prime mover 30, electric motor/generator 32, and electric motor 46 in a manner allowing controller 152 to monitor and/or control one or more aspects of the operation of these components. Based on various operating parameters of prime mover 30, electric motor/generator 32, electric motor 46, and/or other components of power system 11, controller 152 may perform high-level control of power system 11. In doing so, controller 152 may provide to controller 134 of power regulator 104 various target values for operation of power regulator 104, power regulator 102, inverter 100, the primary electrical energy storage device 48, the secondary electrical energy storage device 50, and/or other components of power system 11. For example, controller 152 may communicate to controller 134 target values for voltage and/or electric current in certain portions of power system 11, and controller 134 may control power regulator 104, power regulator 102, inverter 100, switching devices 136, 138 and/or other components of power system 11 to implement the target values. Controller 152 may include any suitable information processing device for controlling the components discussed above. In some embodiments, controller 152 may include one or more microprocessors and/or one or more memory devices programmed to control power system 11 in the manners discussed below.

Power-system controls 26 may also include components for monitoring various aspects of the operation of power system 11. For example, power-system controls 26 may include a voltage sensor 142 for sensing a voltage across terminals 54, 56 of electrical energy storage device 48, which may serve as an indication of a charge level of electrical energy storage device 48. Power-system controls 26 may also include a voltage sensor 144 for sensing a voltage across terminals 118, 119 of power regulator 102. Similarly, power-system controls 26 may include a voltage sensor 154 for sensing the voltage between power lines 110, 111. Additionally, power-system controls 26 may also include a current sensor for sensing a magnitude of electric current in terminal 118, current sensors 148 for sensing a magnitude of electric current flowing between inverter 100 and electric motor 46, and current sensors 150 for sensing a magnitude of electric current flowing between inverter 100 and electric motor/generator 32.

Power-system controls 26 may also include a position sensor 64 for sensing a rotational position of a shaft of electric motor/generator 32. Position sensor 64 may be any type of sensor operable to sense the position of the shaft of electric motor/generator 32. In some embodiments, position sensor 64 may be of a type such that the rotational position of the shaft of electric motor/generator 32 can be discerned from the signal generated by position sensor 64 only when the shaft of electric motor/generator 32 is rotated.

The sensors of power-system controls 26 may be communicatively linked to various components. For example, these sensors may be communicatively linked to controller 134 and/or controller 152, so that power-system controls 26 may monitor the parameters sensed by these sensors. Additionally, power-system controls 26 may include sensors for sensing various other aspects of the operation of power system 11, such as whether prime mover 30 is driving electric motor/generator 32 and whether electric motor/generator 32 is generating electricity. Controller 134 and/or controller 152 and/or other components of power-system controls 26 may also monitor these operating parameters.

Electrical energy storage device 48 and electrical energy storage device 50 may form part of two different branches or circuits of power system 11. As noted above, electrical energy storage device 48 may be electrically isolated from chassis 13 of machine 10, and electrical energy storage device 50 may be electrically referenced to chassis 13 by its connection to chassis 13 at ground 140. As also noted above, power loads 62 and various other electrical components connected to electrical energy storage device 50 may be electrically referenced to chassis 13 of machine 10, such as by connection to ground 140. On the other hand, like electrical energy storage device 48, power regulator 102, inverter 100, power lines 110, 111, electric motor/generator 32, and electric motor 46 may be electrically isolated from chassis 13 and, thus, from electrical energy storage device 50, electrical loads 62, and other chassis referenced electrical components. Thus, electrical energy storage device 50, electrical power loads 62, and other chassis referenced components may form part of one branch or circuit of power system 11, whereas electrical energy storage device 48, power regulator 102, inverter 100, power lines 110, 111, electric motor/generator 32, and electric motor 46 may form part of a separate electrically isolated branch or circuit of power system 11. As noted above, in some embodiments, the branch or circuit containing electrical energy storage device 50 may be a low-voltage branch or circuit, and the branch or circuit containing electrical energy storage device 48 may be a high-voltage branch or circuit. Power regulator 104 may serve as a bridge between the chassis referenced branch or circuit containing electrical energy storage device 50 and the other branch or circuit containing electrical energy storage device 48.

Machine 10 and power system 11 are not limited to the configurations shown in FIGS. 1 and 2 and discussed above. For example, the control tasks handled by power-system controls 26 may be distributed differently between controllers 112, 134, and 152 than discussed above. Additionally, power-system controls 26 may include various other configurations and/or arrangements for controlling the transmission of electricity between the various components of power system 11. Such other configurations of power-system controls 26 may include additional control components communicatively linked to one another and operable to share control tasks, such as other controllers, in addition to controllers 112, 134, and 152. Conversely, in some embodiments, power-system controls 26 may have a single controller in place of two or more of controllers 112, 134, and 152. Additionally, power-system controls 26 may include other numbers and/or configurations of power regulators, switching devices, and other components that transmit power between the power loads and power sources of power system 11. Power system 11 may also include different numbers and/or configurations of electrical energy storage devices than the examples discussed above. Additionally, electric motor 46 may serve a function other than rotating superstructure 20 around axis 34, such as moving other components of machine 10 or supplying mechanical power to propel machine 10. Furthermore, machine 10 may be any of a number of types of machines other than an excavator, including a stationary machine.

### INDUSTRIAL APPLICABILITY

Machine 10 and power system 11 may have use in any application requiring power to perform one or more tasks. During operation of machine 10, power-system controls 26 may activate various electric loads to perform various tasks, such as activating electric motor 46 to rotate superstructure 20 around axis 34.

When machine 10 is operating to perform one or more tasks, power system 11 may provide the electricity required to operate electric motor 46 and any other electric loads from various sources. In some embodiments, power system 11 may provide electricity to electric motor 46 and other electric loads from one or more of electric motor/generator 32, electric energy storage device 48, and/or electric energy storage device 50. For example, when prime mover 30 is operating and driving electric motor/generator 32, power-system controls 26 may operate power electronics module 108 to supply electricity from electric motor/generator 32 to power lines 110, 111, and power-system controls 26 may operate power electronics module 106 to supply electricity from power lines 110, 111 to electric motor 46. Power-system controls 26 may control power electronics module 108 to provide electricity to power lines 110, 111 in various forms. In some embodiments and/or circumstances, power-system controls 26 may control power electronics module 108 to supply direct current electricity to power lines 110, 111 at a relatively high voltage. For example, power-system controls 26 may control power electronics module 108 to maintain the electricity supplied to power lines 110, 111 at about 650 volts DC. While operating prime mover 30 and electric motor/generator 32 to supply electricity to power lines 110, 111, power-system controls 26 may also sometimes transmit electricity from electrical energy storage device 48 to power lines 110, 111 via power regulator 102 to provide additional power to electric motor 46. Similarly, power-system controls 26 may sometimes transmit electricity from power lines 110, 111 to electrical energy storage device 48 via power regulator 102.

For machine 10 to operate properly, various electrical components of power system 11 must be in proper working order. Accordingly, to help ensure proper operation of machine 10, power system 11 and power-system controls 26 may have provisions for facilitating testing of various electrical components of power system 11. For example, power system 11 may be operable in one or more testing modes where power-system controls 26 automatically perform one or more tests of power system 11 and/or provide a state of power system 11 conducive to testing conducted with devices external to power system 11. The testing done when power system 11 is in a testing mode may include validation of the operation of one or more components, calibration of one or more components, and similar tasks undertaken to ensure proper operation power system 11. Power-system controls 26 may enter a testing mode automatically and/or in response to commands from one or more people and/or devices external to power system 11. Power-system controls 26 may operate in a testing mode when prime mover 30 is driving electric motor/generator 32 to supply electricity to power lines 110, 111 and/or when prime mover 30 and electric motor generator 32 are shut down.

Some tests that may be executed on electrical components of power system 11 may require electricity. To enable performance of such tests when power-system controls 26 are in a testing mode and prime mover 30 and electric motor/generator 32 are shut down, power-system controls 26 may provide electricity for testing from electrical energy storage device 50. For example, power-system controls 26 may provide electricity from electrical energy storage device 50 to power lines 110, 111 via power regulators 102, 104. To do so, power-system controls 26 may control switching device 138 to its closed operating state, so that terminals 128, 129 of power regulator 104 are connected to terminals 118, 119 of power regulator 102. With power regulators 102, 104 connected in this manner between electrical energy storage device 50 and power lines 110, 111, power-system controls 26 may operate power regulators 102, 104 to supply electricity from electrical energy storage device 50 to power lines 110, 111.

Power-system controls 26 may also supply electricity from electrical energy storage device 50 to various other portions of power system 11 for purposes of testing, which may include validating the operation of one or more components, calibrating one or more components, and/or similar tasks for ensuring proper operation of power system 11. For example, power-system controls 26 may control switching device 136 to its closed state to provide electricity from electrical energy storage device 50, through power regulator 104, to terminals 54, 56 of electrical energy storage device 48. Additionally, power-system controls 26 may cause electricity to be supplied from electrical energy storage device 50 to electric power loads 62 for purposes of testing, which may include validating the operation of one or more components, calibrating one or more components, and/or similar tasks for ensuring proper operation of power system 11. Power-system controls 26 may control the voltage and other characteristics of the electricity supplied by electrical energy storage device 50 for testing in various manners. Some examples are discussed in more detail below.

With electrical energy storage device 50 supplying electricity to one or more portions of power system 11, the supplied electricity may be used to test various components of power system 11. For example, the electricity supplied by electrical energy storage device 50 may be used to test one or more of current sensors 148, 150 of power system 11. To do so, power-system controls 26 may supply electricity from electrical energy storage device 50, through power regulators 102, 104, to power lines 110, 111. With power lines 110, 111 electrified with energy from electrical energy storage device 50, power-system controls 26 may operate power electronics module 106 and power electronics module 108 to supply a controlled electric current to each of electric motor/generator 32 and electric motor 46. In response, if current sensors 148, 150 are working properly, they will send signals to power-system controls 26 reflecting the current transmitted to electric motor/generator 32 and electric motor 46, respectively. Power-system controls 26 may validate that current sensors 148, 150 are operating correctly by, for example, verifying that the signals from current sensors 148, 150 are consistent with the magnitude of electric current that power-system controls 26 controlled power electronics modules 106, 108 to transmit.

Additionally, the testing of a current sensor, such as current sensors 148, 150, may involve calibrating one or more of current sensors 148. For example, to calibrate current sensor 148, power-system controls 26 may send from power electronics module 106 to electric motor 46 an electric current with a magnitude that can be reliably known independently of current sensor 148. The known value of the electric current sent to the electric motor 46 and the signal received from current sensor 148 may then be used to calibrate current sensor 148. Calibrating a current sensor may involve adjusting various parameters to ensure that power-system controls 26 can use the signal from current sensor 148 as an accurate indication of the current flowing between power electronics module 106 and electric motor 46. For example, calibrating current sensor 148 may involve adjusting data stored in one or more of controllers 112, 134, and 152 regarding the relationship between the signal from current sensor 148 and the actual value of the current flowing between power electronics module 106 and electric motor 46.

In the foregoing methods of calibrating current sensor 148, any suitable method may be used for independently reliably knowing the magnitude of electric current supplied from power electronics module 106 to electric motor 46. For example, it may be possible to reliably know the magnitude of electric current sent to the electric motor 46 based on the manner in which power-system controls 26 operate power electronics module 106 and/or by using information from another current sensor (not shown) whose output signal is considered a reliable reference for calibration. Similar approaches may be used to calibrate other current sensors of power system 11.

In addition to current sensors, various other sensors of power system 11 may be tested with electricity supplied by electrical energy storage device 50. For example, voltage sensors 142, 144, 154 may be tested. To enable testing voltage sensor 144 with electricity from electrical energy storage device 50, power-system controls 26 may control switching device 138 to its closed operating state, so that terminals 128, 129 of power regulator 104 are connected to terminals 118, 119 of power regulator 102. To test voltage sensor 144, power-system controls 26 may control power regulator 104 to receive electricity from electrical energy storage device 50 and supply a controlled voltage from power regulator 104 to terminals 118, 119 of power regulator 102. With such a controlled voltage supplied to terminals 118, 119, power-system controls 26 may determine whether voltage sensor 144 is operating correctly by determining whether voltage sensor 144 supplies to power-system controls 26 a signal accurately indicating the voltage supplied to terminals 118, 119. With electricity supplied to terminals 118, 119 of power regulator 102, power-system controls 26 may also test voltage sensor 154 by supplying a controlled voltage from power regulator 102 to power lines 110, 111 and determining whether voltage sensor 154 generates a signal accurately indicating the controlled voltage supplied to power lines 110, 111. Power-system controls 26 may similarly test voltage sensor 142 by closing switching device 136 and determining whether voltage sensor 142 generates a signal accurately indicating the voltage supplied to terminals 54, 56 by power regulator 104.

To perform the foregoing tests, it may be helpful to reliably know the voltage supplied to the various voltage sensors independently of the signals from the voltage sensors themselves. Various approaches may be used to reliably know the voltage supplied to each voltage sensor independently of the signal from the voltage sensor. For example, the voltage supplied to each voltage sensor may be known from the manner in which the components supplying the voltage are controlled and/or by using another voltage sensor considered reliable for calibration purposes to sense voltage. Where another voltage sensor is used to validate another, the two voltage sensors may sense voltage in the same portion of the electrical system or in portions of the electrical system that are connected to one another.

The testing of one or more voltage sensors of power system 11 may also involve calibration of one or more of the sensors. If the voltage applied to a voltage sensor is reliably known independently of the signal from the voltage sensor, the known voltage and the signal from the voltage sensor may be used to calibrate the voltage sensor. Calibrating a voltage sensor may involve adjusting various parameters to ensure that power-system controls 26 can use the signal from a voltage sensor as an accurate indication of the voltage in the portion of power system 11 sensed by the voltage sensor. For example, calibrating a voltage sensor may involve adjusting data stored in one or more of controllers 112, 134, and 152 regarding the relationship between the signal from the voltage sensor and the actual value of the voltage in the portion of the power system 11 sensed by the voltage sensors. The foregoing techniques may be employed with voltage sensors 142, 144, 154, and other voltage sensors of power system 11.

Electricity from electrical energy storage device 50 may also be used to test the continuity of various components of power system 11. For example, in testing current sensors 148, 150 and voltage sensors 142, 144, 154 in the manners discussed above, power-system controls 26 may verify the continuity of all of the components between electrical energy storage device 50 and the sensors 142, 144, 148, 150, and 154. Power-system controls 26 may also test the continuity of various other components of power system 11 using any known or suitable method, including sending electricity to various other components of power system 11 and verifying that those components receive the electricity.

Electricity from electrical energy storage device 50 may also be used to test the electrical insulation of one or more components of power system 11. For example, the electrical insulation (not shown) of the windings (not shown) of electric motor 46 may be tested with electricity from electrical energy storage device 50. To enable doing so, power-system controls 26 may close switching device 138 and supply electricity from electrical energy storage device 50, through power regulators 104 and 102, to power lines 110, 111.

With power lines 110, 111 electrified with energy from electrical energy storage device 50, power-system controls 26 may use any known or suitable approach for testing the electrical insulation of the windings of electric motor 46. Some approaches that power-system controls 26 may use to do so may involve creating a leakage current from power lines 110, 111 to ground through a known electrical resistance and evaluating the electrical insulation of the electric motor 46 based at least in part on measured parameters related to the leakage current and insulation values. Power-system controls 26 may, for example, charge bulk capacitor 114 to a known voltage value with electricity from electrical energy storage device 50 by supplying electricity from power regulator 102 to power lines 110, 111. After charging bulk capacitor 114 to the known voltage level, power-system controls 26 may then discontinue supplying electricity to power lines 110, 111. Subsequently, power-system controls 26 may allow the charge on bulk capacitor 114 to discharge to ground through a known resistance, while initially controlling power electronics module 106 to keep the windings of electric motor 46 disconnected from power lines 110, 111. While bulk capacitor 114 is discharging, power-system controls 26 may then control power electronics module 106 to connect one or more phases of the windings of electric motor 46 to power lines 110, 111 and, thus, bulk capacitor 114. By monitoring how connecting the windings of electric motor 46 to the bulk capacitor 114 affects the voltage on bulk capacitor 114, power-system controls 26 may estimate the effective insulating value of the electrical insulation of the windings of electric motor 46. Power-system controls 26 may use similar approaches to test the electrical insulation of various other components of power system 11.

When power-system controls 26 are operating in a testing mode and one or more electrical components of power system 11 are being tested using electricity from electrical energy storage device 50, power-system controls 26 may control the electricity supplied from electrical energy storage device 50 in various ways. In some embodiments, power-system controls 26 may control the electricity supplied to various portions of power system 11 to voltage levels lower than what those components receive during normal operation of power system 11. For example, during testing of one or more electrical components connected to power lines 110, 111, power-system controls 26 may control power regulators 102, 104 to supply electricity to power lines 110, 111 at a lower voltage than power-system controls 26 maintain the electricity supplied to power lines 110, 111 by electric motor/generator 32 during normal operation. As noted above, power-system controls 26 may maintain the voltage on power lines 110, 111 at or above about 650 volts when electric motor/generator 32 is supplying electricity to power lines 110, 111 to power electric motor 46. During operation in at least some testing modes, power-system controls 26 may supply electricity from electrical energy storage device 50 to power lines 110, 111 at a lower voltage, such as about 50 volts or less.

The disclosed approaches of supplying electricity from electrical energy storage device 50 to test one or more electrical components of power system 11 may provide a number of advantages. For example, supplying testing electricity at a relatively low voltage may help ensure that the components of power system 11 do not incur damage due to receiving excessive electricity during testing. Indeed, the value of 50 volts or less is generally considered a level at which it is particularly safe for an individual to work with a live electrical system. Thus, by maintaining the testing electricity in certain portions of power system 11 at 50 volts or less, power-system controls 26 may allow individuals to test various electrical components of power system 11 with a high level of safety. Supplying the electricity from electrical energy storage device 50 may provide similar advantages because electrical energy storage device 50 may be capable of supplying only a limited amount of electric current. Thus, if an unintended electrical short or similar problem occurs, electrical energy storage device 50 may expend all of its stored energy before sufficient electric current flows to cause damage to components. Additionally, providing electricity for testing with electrical energy storage device 50 may generate little or no electrical and electromagnetic noise, thereby providing an environment conducive to accurate testing. Furthermore, providing the electricity from electrical energy storage device 50 may reduce or eliminate any need to provide electricity from one or more devices external to machine 10 to conduct testing of electrical components of power system 11. Additionally, because power regulators 102, 104 may be able to supply electricity from electrical energy storage device 50 to other portions of power system 11 at relatively high voltages, it may be possible to test various components with a higher degree of accuracy in some circumstances than would be possible with lower voltage electricity. For example, the relatively high voltage at which power regulators 102, 104 may be able to supply electricity may be conducive to accurate testing of voltage sensors and electrical insulation.

Methods of operating power system 11 are not limited to the examples discussed above. For instance, electricity for testing may be supplied from electrical energy storage device 50 at different voltages than the examples discussed above. Similarly, electricity supplied to various portions of power system 11 during normal operation may be supplied at different voltages than the examples discussed above. Additionally, power-system controls 26 may use methods different than those discussed above to test one or more electrical components of power system 11. Similarly, one or more of the electrical tests discussed above may be performed partially or fully manually under the control of one or more service personnel, rather than being performed automatically by power-system controls 11. Additionally, various electrical components other than those discussed above may be tested using electricity from electrical energy storage device 50.

It will be apparent to those skilled in the art that various modifications and variations can be made in the disclosed power system and methods without departing from the scope of the disclosure. Other embodiments of the disclosed power system and methods will be apparent to those skilled in the art from consideration of the specification and practice of the power system and methods disclosed herein. It is intended that the specification and examples be considered as exemplary only, with a true scope of the disclosure being indicated by the following claims and their equivalents.

What is claimed is:

1. A power system, comprising:
a prime mover drivingly connected to an electric generator;
an electric power load;
an electrical energy storage device; and
power-system controls configured to:
selectively operate the prime mover and the electric generator to power the electric power load by supplying electricity at a first voltage; and
selectively supply electricity from the electrical energy storage device at a second voltage during testing of one or more electrical components of the power system with the electricity supplied at the second voltage, the second voltage being lower than the first voltage.

2. The power system of claim 1, wherein the second voltage is about 50 volts or less.

3. The power system of claim 1, wherein the power-system controls are configured to automatically test one or more electrical components of the power system while supplying electricity from the electrical energy storage device at the second voltage.

4. The power system of claim 1, wherein the power-system controls are configured to automatically test one or more current sensors of the power system while supplying electricity from the electrical energy storage device at the second voltage.

5. The power system of claim 1, wherein the power-system controls are configured to automatically test insulation of one or more electrical conductors while supplying electricity from the electrical energy storage device at the second voltage.

6. The power system of claim 1, wherein the power-system controls are configured to automatically test one or more voltage sensors while supplying electricity from the electrical energy storage device at the second voltage.

7. The power system of claim 1, wherein the power-system controls are configured to automatically test insulation of one or more electrical conductors of at least one of the electric generator and the electric power load while supplying electricity from the electrical energy storage device at the second voltage.

8. A method of operating a power system, the power system including a prime mover, an electric generator drivingly connected to the prime mover, an electric power load, and an electrical energy storage device, the method comprising:
selectively operating the prime mover and the electric generator to supply electricity at a first voltage to power the electric power load;
selectively supplying electricity at a second voltage with the electrical energy storage device while testing one or more electrical components of the power system with the electricity supplied from the electrical energy storage device at the second voltage, wherein the second voltage is less than the first voltage.

9. The method of claim 8, wherein the first voltage is about 50 volts or less.

10. The method of claim 8, wherein:
the electrical energy storage device is a secondary electrical energy storage device;
the power system further includes a primary electrical energy storage device; and
the method further includes selectively transmitting electricity from the primary electrical energy storage device to the electric power load while operating the prime mover and the electric generator to supply electricity to the electric power load.

11. The method of claim 8, wherein testing one or more electrical components of the power system with the electricity supplied from the electrical energy storage device includes testing one or more current sensors.

12. The method of claim 8, wherein testing one or more electrical components of the power system with the electricity supplied from the electrical energy storage device includes testing one or more voltage sensors.

13. The method of claim 8, wherein testing one or more electrical components of the power system with the electricity supplied from the electrical energy storage device includes testing continuity of one or more components of the electrical power system.

14. The method of claim 8, wherein testing one or more electrical components of the power system with the electricity supplied from the electrical energy storage device includes testing insulation of one or more electrical components of the power system.

15. The method of claim 8, wherein testing one or more electrical components of the power system with the electricity supplied from the electrical energy storage device includes the power-system controls automatically testing one or more electrical components of the power system.

16. The method of claim 8, wherein:
selectively operating the prime mover and the electric generator to supply electricity at the first voltage to power the electric power load includes transmitting the electricity supplied to the power load with a power line; and
selectively supplying electricity at the second voltage with the electrical energy storage device includes supplying electricity from the electrical energy storage device to the power line with at least one power regulator.

17. A machine, comprising:
a power system, including
an electric motor,
an engine drivingly connected to an electric generator,
a power line connected between the electric generator and the electric motor, the power line being operable to transmit electricity between the electric generator and the electric motor,
a first electrical energy storage device,
a second electrical energy storage device,
power-system controls configured to:
selectively operate the engine and the electric generator to supply electricity to the power line while exchanging electricity between the first electrical energy storage device and the power line;
selectively operate the power system in a testing mode with the engine shut down and the second electrical energy storage device supplying electricity to the power line while tests are performed on one or more electrical components of the power system with the electricity supplied to the power line by the second electrical energy storage device.

18. The machine of claim 17, wherein:
selectively operating the engine and the electric generator to supply electricity to the power line includes selectively supplying the electricity to the power line at a first voltage; and
selectively supplying electricity to the power line with the second electrical energy storage device in the testing mode includes selectively supplying electricity from the second electrical energy storage device to the power line at a second voltage, the second voltage being lower than the first voltage.

19. The machine of claim 17, wherein selectively supplying electricity to the power line with the second electrical energy storage device in the testing mode includes maintaining the electricity supplied from the second electrical energy storage device to the power line at about 50 volts or less while in the testing mode.

20. The machine of claim 17, wherein:
the machine further includes a chassis;
the first electrical energy storage device is grounded to the chassis; and
the second electrical energy storage device is electrically isolated from the chassis.
